(19) United States
(12) Patent Application Publication
(10) Pub. No.: US 2014/0321815 A1
(43) Pub. Date: Oct. 30, 2014

(54) OPTICAL CONNECTOR AND CIRCUIT BOARD OF SAME

(71) Applicant: HON HAI PRECISION INDUSTRY CO., LTD., New Taipei (TW)

(72) Inventor: KAI-WEN WU, New Taipei (TW)

(73) Assignee: HON HAI PRECISION INDUSTRY CO., LTD., New Taipei (TW)

(21) Appl. No.: 14/261,517

(22) Filed: Apr. 25, 2014

(30) Foreign Application Priority Data
Apr. 26, 2013 (TW) 102115178

(51) Int. Cl. H05K 1/11; G02B 6/43

(52) U.S. Cl. CPC H05K 1/111; G02B 6/43; H05K 2201/10621
USPC 385/88; 174/261

(57) ABSTRACT

A circuit board includes a first circuit substrate configured for mounting a driving chip and a second circuit substrate positioned on and electrical connected to the first circuit substrate. The second circuit substrate comprises two first top pads, and each of the first top pads can be configured for mounting a light emitter. The second circuit substrate is arranged on the first circuit substrate and can be employed to mount the light emitters, which can improve the precision in the process of mounting the light emitters.

### FIELD

The present disclosure relates to optical connectors, and particularly to an optical connector having a circuit board, and a circuit board.

### BACKGROUND

Optical connectors include a circuit board, a number of light emitters for emitting light signals, a number of light receivers for receiving light signals, a driving chip, and a transimpedance amplifier. The circuit board includes a number of connecting pads. The light emitters, the light receivers, the driving chip and the transimpedance amplifier are respectively positioned on a corresponding connecting pad. The light emitters must be positioned precisely on the circuit board.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a schematic view of an optical connector in accordance with an exemplary embodiment.

FIG. 2 is a cross-sectional view of the optical connector of FIG. 1.

FIG. 3 is a cross-sectional view of a second circuit substrate of the optical connector in FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.” The references “a plurality of” and “a number of” mean “at least two.”

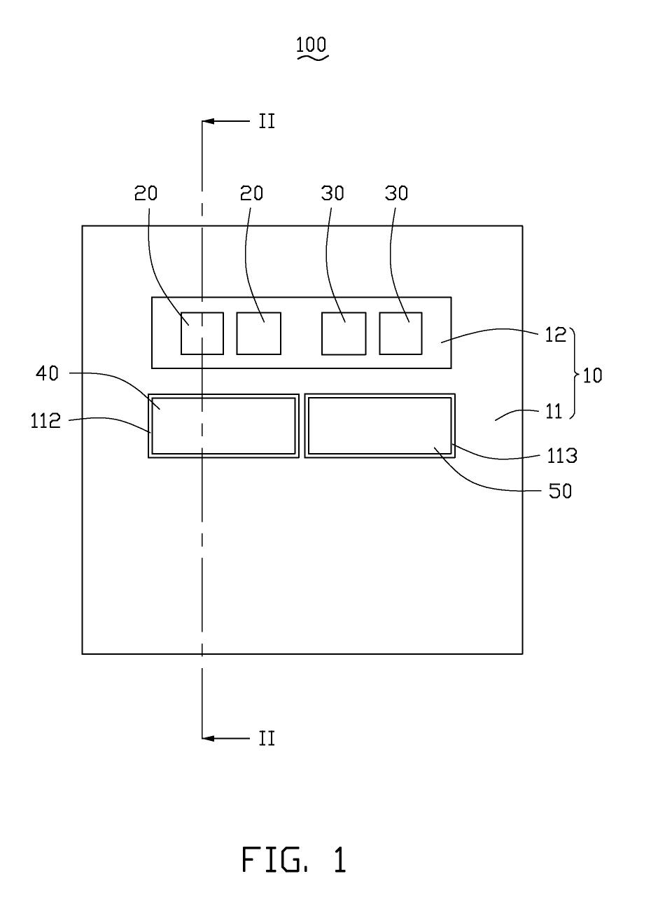

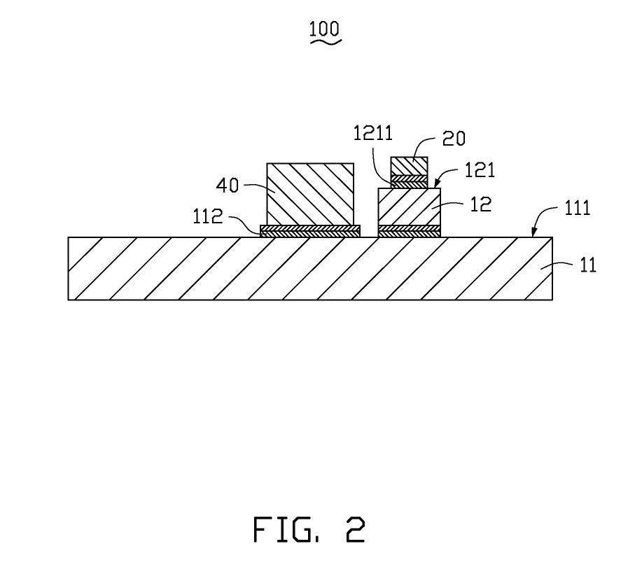

FIGS. 1-2 illustrate an optical connector 100 according to an exemplary embodiment. The optical connector 100 can include a circuit board 10, two light emitters 20, such as laser diodes, two light receivers 30, such as photo diodes, a driving chip 40, and a transimpedance amplifier 50.

The circuit board 10 can include a first circuit substrate 11 and a second circuit substrate 12. The first circuit substrate 11 and the second circuit substrate 12 all include electrical wires.

The first substrate 11 can include a first mounting surface 111. The first substrate 11 can include a first pad 112 and a second pad 113. The first pad 112 and the second pad 113 can be exposed from the first mounting surface 111. The first pad 112 can be configured for mounting the driving chip 40. The second pad 113 can be configured for mounting the transimpedance amplifier 50. In this embodiment, the first pad 112 and the second pad 113 can be all rectangular-shaped.

In one embodiment, the first pad 112 can include a number of connecting blocks matching electrodes of the driving chip 40, and the second pad 113 can include a number of connecting blocks matching electrodes of the transimpedance amplifier 50.

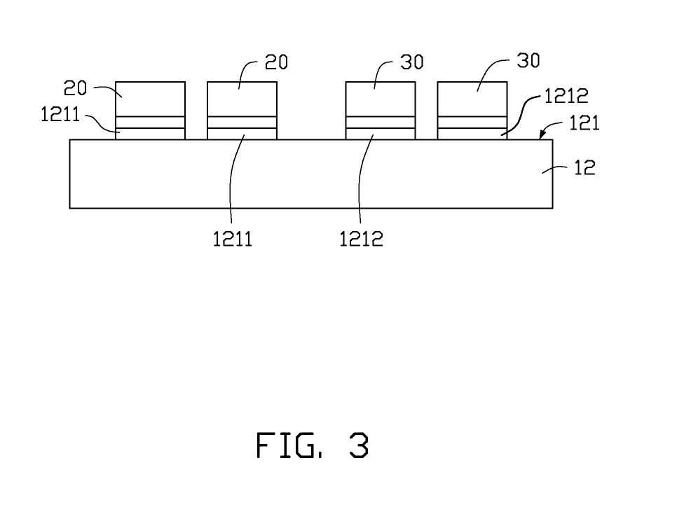

FIG. 3 illustrates that the second circuit substrate 12 can be positioned on and electrical connected to the first circuit substrate 11. A size of the second circuit substrate 12 can be less than that of the first circuit substrate 11. The second substrate 12 can include a second mounting surface 121. The second mounting surface 121 can be away from the first circuit substrate 11. The second circuit substrate 12 can include two first top pads 1211 and two second top pads 1212. The first top pads 1211 and the second top pads 1212 can be exposed in the second mounting surface 121. Each of the first top pads 1211 can correspond to and can be configured for mounting one of the two light emitters 20. A shape of the first top pad 1211 can be the same as a shape of an orthogonal projection of the corresponding light emitter 20 on the second circuit substrate 12. A size of the first top pad 1211 can be equal to a size of an orthogonal projection of the corresponding light emitter 20 on the second circuit substrate 12. Each of the second top pads 1212 can correspond to and can be configured for mounting one of the two light receivers 30. A shape of the second top pad 1212 can be the same as a shape of an orthogonal projection of the corresponding light receiver 30 on the second circuit substrate 12. A size of the second top pad 1212 can be equal to a size of an orthogonal projection of the corresponding light receiver 30 on the second circuit substrate 12. In this embodiment, the first top pad 1211 and the second top pad 1212 are all rectangular-shaped.

In the embodiment, the first top pad 1211 can include a number of connecting blocks to match electrodes of the light emitter 20, and the second pad 113 can include a number of connecting blocks to match electrodes of the light receiver 30.

Each of the light emitters 20 can correspond to and can be mounted on one of the first top pads 1211. Each of the light emitters 20 can be configured for generating and emitting a light signal. In this embodiment, each of the light emitter 20 is a laser diode. Each of the light emitters 20 can couple with a corresponding optical fiber (not shown) through a lens (not shown) to send out the light signal. Each of the light emitters 20 can be electrically coupled to the first circuit substrate 11 through the second circuit substrate 12.

The driving chip 40 can be mounted on the first pad 112. The driving chip 40 can be configured for controlling each of the light emitters 20 to generate and emit a light signal. The driving chip 40 can be electrically coupled to the light emitters 20 arranged on the second circuit substrate 12 through the first circuit substrate 11.

Each of the light receivers 30 can correspond to and can be mounted on one of the second top pads 1212. Each of the light receivers 30 can be configured for receiving light signal sent from each of the light emitters 20 and translating the light signal to a current signal. In this embodiment, each of the light receivers 30 can be a photodiode. Each of the light receivers 30 can be coupled with a corresponding optical fiber (not shown) through a lens (not shown) to receive the light signal. Each of the light receivers 30 can be electrically coupled to the first circuit substrate 11 through the second circuit substrate 12.

The transimpedance amplifier 50 can be mounted on the second pad 113. The transimpedance amplifier 50 can be configured for translating the current signal sent from each of the light receivers 30 to a voltage signal. The transimpedance amplifier 50 can be electrically coupled to the light receivers 30 arranged on the second circuit substrate 12 through the first circuit substrate 11.

In other embodiments, the shape of the first pad 112, the second pad 113, the first top pad 1211 and the second top pad 1212 also can be other shapes.

In other embodiments, the number of the light emitters 20 and the number of the light receivers 30 are not limited to two, but can be one or more than two.

In this embodiments, the second circuit substrate 12 arranged on the first circuit substrate 11 can be employed to mount the light emitters 20, which can improve the precision in the process of mounting the light emitters 20.

Particular embodiments are shown and described by way of illustration only. The principles and the features of the present disclosure may be employed in various and numerous embodiments thereof without departing from the scope of the disclosure as claimed. The above-described embodiments illustrate the scope of the disclosure but do not restrict the scope of the disclosure.

What is claimed is:

1. A circuit board, comprising:
a first circuit substrate configured for mounting a driving chip; and
a second circuit substrate positioned on and electrical connected to the first circuit substrate, the second circuit substrate comprising two first top pads, each of the first top pads configured for mounting a light emitter.

2. The circuit board of claim 1, wherein the first circuit substrate comprise a first pad, the first pad configured for mounting a driving chip.

3. The circuit board of claim 2, wherein the second circuit substrate further comprises two second top pads, each of the second top pads configured for mounting a light receiver.

4. The circuit board of claim 3, wherein the first circuit substrate further comprise a second pad, the second pad configured for mounting a transimpedance amplifier.

5. The circuit board of claim 4, wherein the first top pads, the second top pads, the first pad, and the second pad are all rectangular-shaped.

6. An optical connector, comprising:
a circuit board, comprising:
a first circuit substrate configured for mounting a driving chip; and
a second circuit substrate positioned on and electrical connected to the first circuit substrate, the second circuit substrate comprising two first top pads, each of the first top pads configured for mounting a light emitter;
two light emitters, each of the light emitters corresponding to and mounted on one of the first top pads, each of the light emitters configured for generating and emitting a light signal; and
a driving chip mounted on the first circuit substrate, the driving chip configured for controlling the light emitters to generate and emit the light signals.

7. The optical connector of claim 6, wherein a shape of the first top pad is the same as a shape of an orthogonal projection of the corresponding light emitter on the second circuit substrate.

8. The optical connector of claim 7, wherein a size of the first top pad is equal to a size of an orthogonal projection of the corresponding light emitter on the second circuit substrate.

9. The optical connector of claim 6, wherein the first top pads are all rectangular-shaped.

10. The optical connector of claim 6, wherein the second circuit substrate further comprises two second top pads, and two light receivers being separately mounted on the two second top pads, each of the light receivers configured for receiving light signal sent from the light emitters and translating the received light signal to a current signal.

11. The optical connector of claim 10, wherein a shape of the second top pad is the same as a shape of an orthogonal projection of the corresponding light receiver on the second circuit substrate.

12. The optical connector of claim 11, wherein a size of the first top pad is equal to a size of an orthogonal projection of the corresponding light receiver on the second circuit substrate.

13. The optical connector of claim 10, wherein the second top pads are all rectangular-shaped.

14. The optical connector of claim 10, further comprising a transimpedance amplifier mounted on the first circuit substrate, the transimpedance amplifier configured for translating the current signal sent from each of the light receivers to voltage signal.
